(19) United States
(12) Patent Application Publication
(10) Pub. No.: US 2015/0211675 A1
(43) Pub. Date: Jul. 30, 2015

(54) DEVICE ADJUSTABLE SUPPORT

(71) Applicant: Top Victory Investments Limited, Kowloon (HK)

(72) Inventors: Jenq-Huey SHYU, New Taipei City (TW); Yao-Jen Yeh, New Taipei City (TW); Tung-Jung Hsueh, New Taipei City (TW); Chia-Yu Liu, New Taipei City (TW); Yi-Sheng Lin, New Taipei City (TW)

(73) Assignee: Top Victory Investments Limited, Kowloon (HK)

(21) Appl. No.: 14/164,639

(22) Filed: Jan. 27, 2014

(51) Int. Cl. F16M 11/12; F16M 11/18; H05K 7/18

(52) U.S. Cl. CPC F16M 11/12; H05K 7/183; F16M 11/126; F16M 11/128; F16M 11/18

(57) ABSTRACT

A device adjustable support comprises a bracket plate and a coupling mechanism including: a guiding track that is securely integrated with the bracket plate and that extends along a first curved and non-circumferential line; a course-keeping member that is integrated with the bracket plate; a first connector that is connected slidably to the guiding track so as to be slidable on the bracket plate along the first curved and non-circumferential line; and a second connector that is connected movably to the course-keeping member so as to keep sliding movement of the first connector along the guiding track.

### BACKGROUND OF THE INVENTION

1. Field of the Invention

This invention relates to a device adjustable support for adjustably supporting and adjusting an electronic device that is supported thereon, more particularly to a device adjustable support for supporting a display in an adjustable manner that can simultaneously turn and change the elevation of the display.

2. Description of the Related Art

Wide screen displays have the advantages of allowing users to view images in either a landscape or a portrait manner. A conventional display support normally includes a base, an upright post extending upwardly from the base, a bracket plate secured to a top end of the upright post, and a coupling mechanism interconnecting the bracket plate and a display for supporting and permitting positional adjustment of the display on the display support. To change the display from a landscape position to a portrait position, the user has to lift the display a height relative to the bracket plate in order to prevent interference with the base and then rotate the display by 90 degrees. As such, operation of the conventional display support is inconvenient.

### SUMMARY OF THE INVENTION

Therefore, an object of the present invention is to provide a device adjustable support that can overcome the aforesaid drawback associated with the prior art.

According to this invention, there is provided a device adjustable support for adjustably supporting an electronic device. The device adjustable support comprises a bracket plate and a coupling mechanism that is adapted to couple the electronic device to the bracket plate. The coupling mechanism includes: a guiding track that is securely integrated with the bracket plate and that extends along a first curved and non-circumferential line; a course-keeping member that is integrated with the bracket plate; a first connector that is adapted to be secured to a surface of the electronic device and that is connected slidably to the guiding track so as to be slidable on the bracket plate along the first curved and non-circumferential line; and a second connector that is adapted to be secured to the surface of the electronic device, that is spaced apart from the first connector, and that is connected movably to the course-keeping member so as to keep sliding movement of the first connector along the guiding track when the electronic device is simultaneously turned and changed in height relative to the bracket plate.

### BRIEF DESCRIPTION OF THE DRAWINGS

In drawings which illustrate embodiments of the invention,

FIG. 1 is a perspective view of the first preferred embodiment of a device adjustable support according to the present invention;

FIG. 2 is an exploded perspective back view of the first preferred embodiment;

FIG. 3 is an exploded perspective front view of the first preferred embodiment;

FIG. 4 is a fragmentary schematic back view of the first preferred embodiment, illustrating a state where an electronic device supported thereon is disposed at a horizontal position;

FIG. 5 is a fragmentary schematic back view of the first preferred embodiment, illustrating another state where the electronic device is disposed at a position off from the horizontal position;

FIG. 6 is a fragmentary schematic back view of the first preferred embodiment, illustrating another state where the electronic device is disposed at a vertical position;

FIG. 7 is a perspective view of the second preferred embodiment of the device adjustable support according to the present invention;

FIG. 8 is an exploded perspective back view of the second preferred embodiment;

FIG. 9 is an exploded perspective front view of the second preferred embodiment;

FIG. 10 is a fragmentary schematic back view of the second preferred embodiment, illustrating a state where the electronic device supported thereon is disposed at a horizontal position;

FIG. 11 is a fragmentary schematic back view of the second preferred embodiment, illustrating another state where the electronic device is disposed at a position off from the horizontal position; and

FIG. 12 is a fragmentary schematic back view of the second preferred embodiment, illustrating another state where the electronic device is disposed at a vertical position.

### DETAILED DESCRIPTION OF THE PREFERRED EMBODIMENTS

Before the present invention is described in greater detail with reference to the accompanying preferred embodiments, it should be noted herein that like elements are denoted by the same reference numerals throughout the disclosure.

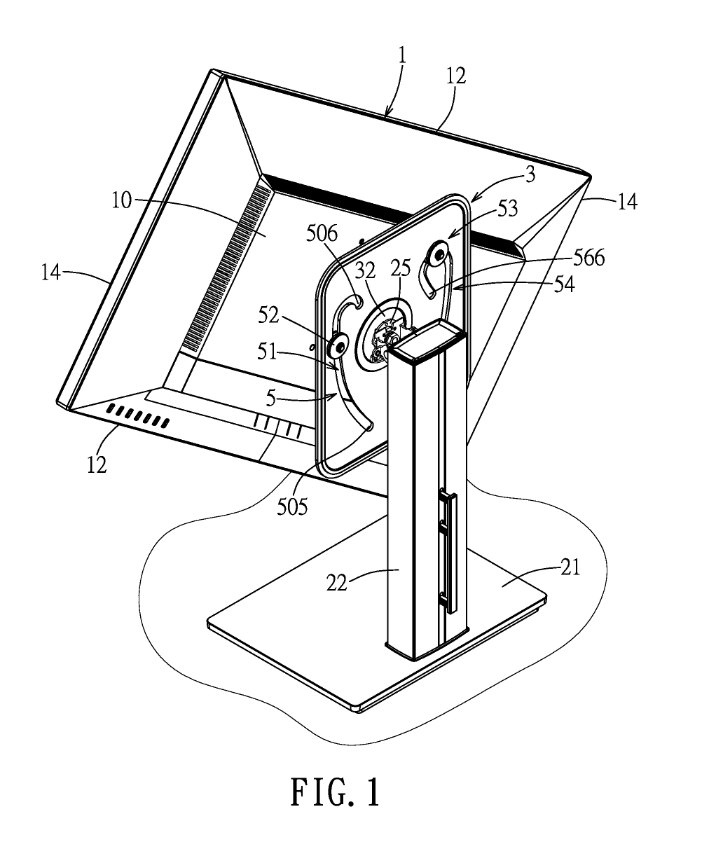

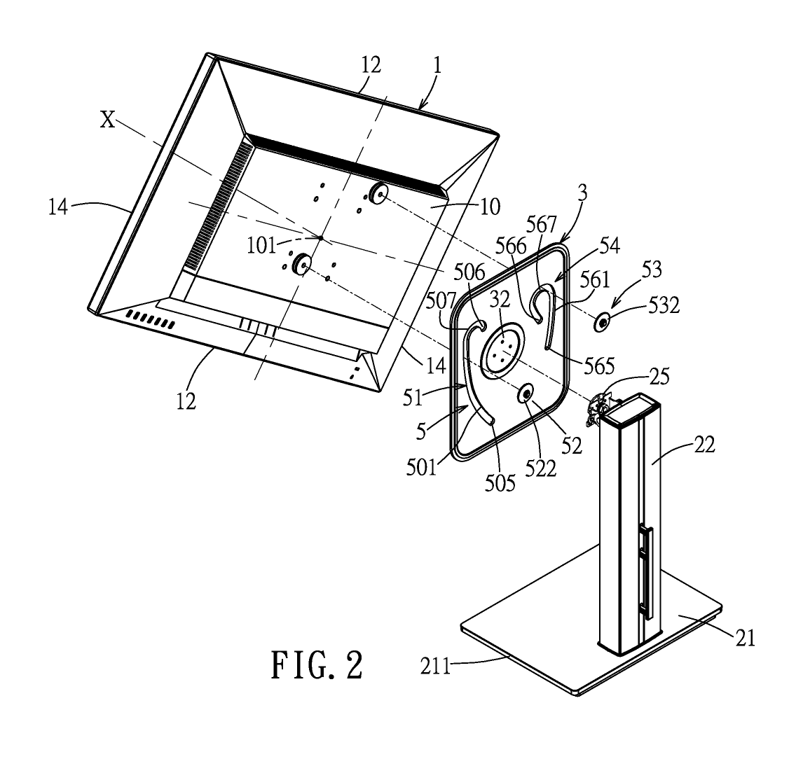

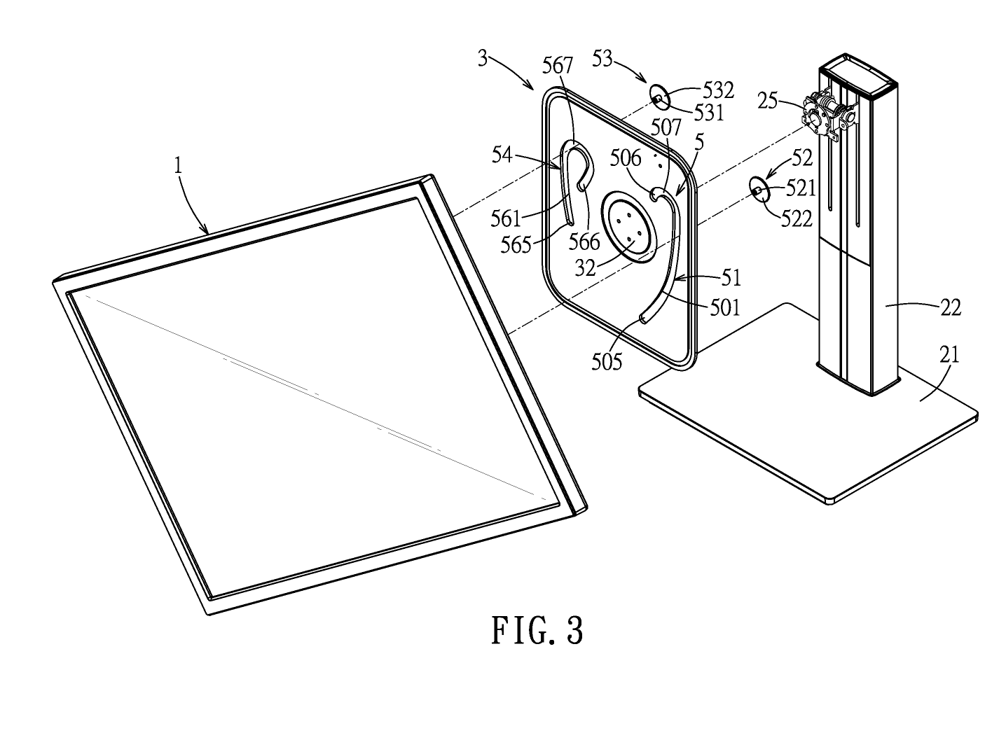

FIGS. 1 to 4 illustrate the first preferred embodiment of a device adjustable support for adjustably supporting an electronic device 1, such as a wide screen display, according to the present invention. The device adjustable support includes a base 21, an upright post 22 that extends upright from the base 21, a bracket plate 3 that is secured to a top end of the upright post 22, and a coupling mechanism 5 that couples the electronic device 1 to the bracket plate 3.

The electronic device 1 is rectangular in shape, and has two opposite first sides 12, two opposite second sides 14, and a flat rectangular back surface 10 with a geometric center 101. The first sides 12 are opposite to each other in a direction perpendicular to an opposing direction of the second sides 14, and are greater in length than the second sides 14. The electronic device 1 defines a horizontal axis (X) that extends through a center of mass of the electronic device 1, that is perpendicular to the back surface 10, and that intersects the back surface 10 at the geometric center 101 of the back surface 10. The upright post 22 defines a vertical axis (Y) that extends along the length of the upright post 22 through a middle point of a width of the upright post 22, and that is perpendicular to the horizontal axis (X). The width of the upright post 22 is measured in a direction perpendicular to the horizontal axis (X) and the vertical axis (Y).

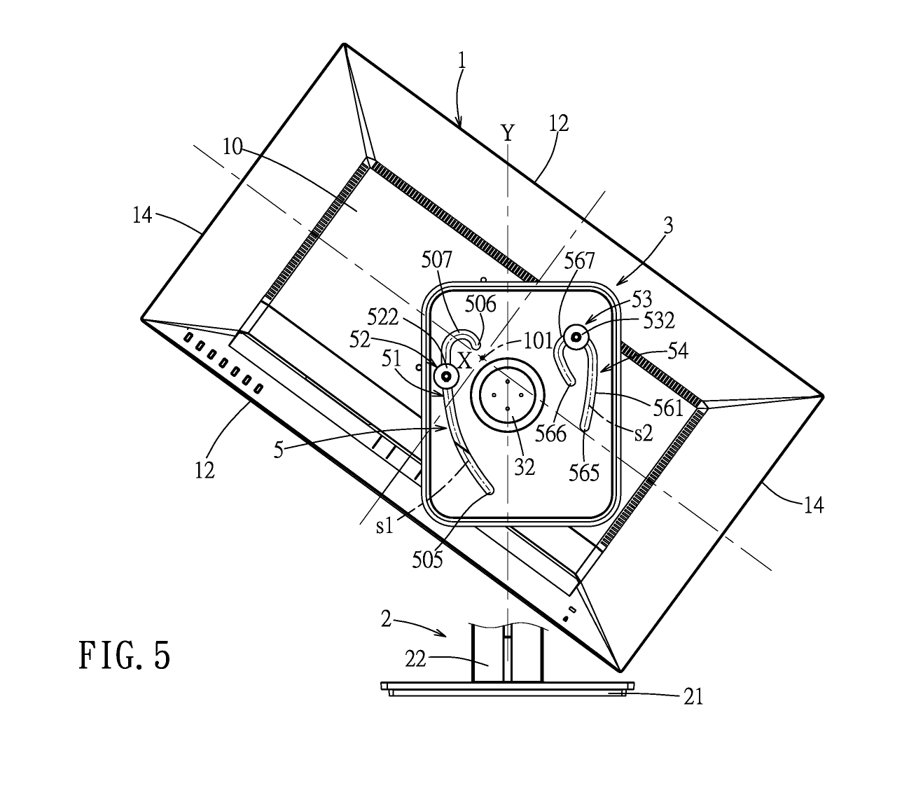

The coupling mechanism 5 includes: a guiding track 51 that is securely integrated with the bracket plate 3 and that extends along a first curved and non-circumferential line (s1) (see FIG. 5); a course-keeping member 54 that is integrated with the bracket plate 3; a first connector 52 that is secured to the back surface 10 of the electronic device 1 and that is connected slidably to the guiding track 51 so as to be slidable on the bracket plate 3 along the first curved and non-circumferential line (s1); and a second connector 53 that is secured to the back surface 10 of the electronic device 1, that is spaced apart from the first connector 52, and that is connected movably to the course-keeping member 54 so as to keep sliding movement of the first connector 52 along the guiding track 51 when the electronic device 1 is simultaneously turned and changed in height relative to the bracket plate 3.

In this embodiment, the bracket plate 3 is formed with a first curved groove that is defined by a first groove-defining wall 501 and that serves as the guiding track 51. The first connector 52 has a shaft portion 521 and a head portion 522. The shaft portion 521 is connected to and extends from the back surface 10 of the electronic device 1 through the first curved groove so as to be slidable on the first groove-defining wall 501. The head portion 522 is anchored at one side of the bracket plate 3 opposite to the electronic device 1.

The bracket plate 3 is further formed with a second curved groove that is defined by a second groove-defining wall 561 and that serves as the course-keeping member 54. The second connector 53 has a shaft portion 531 and a head portion 532. The shaft portion 531 of the second connector 53 is connected to and extends from the electronic device 1 through the second curved groove so as to be slidable on the second groove-defining wall 561. The head portion 532 of the second connector 53 is anchored at said one side of the bracket plate 3 opposite to the electronic device 1.

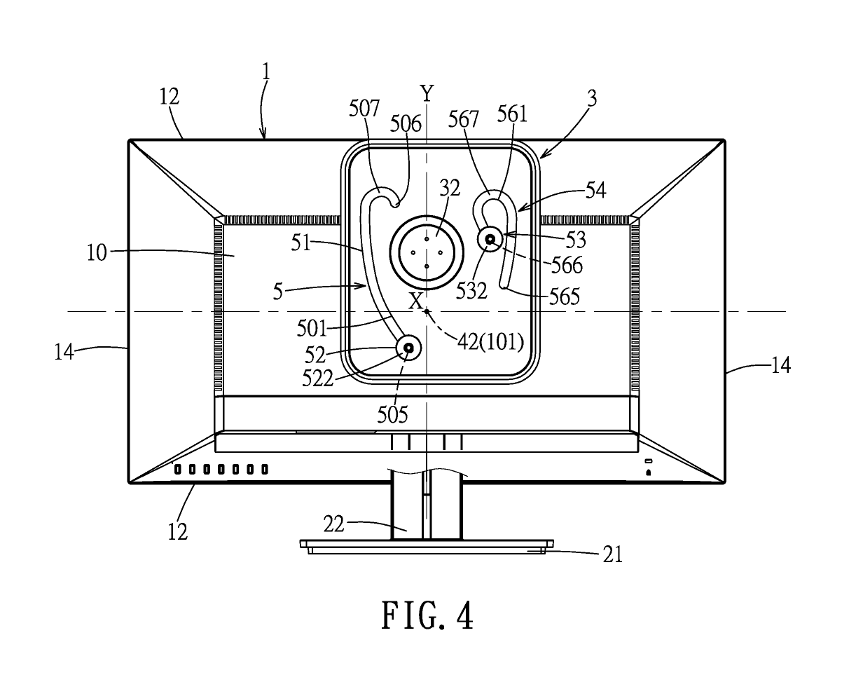

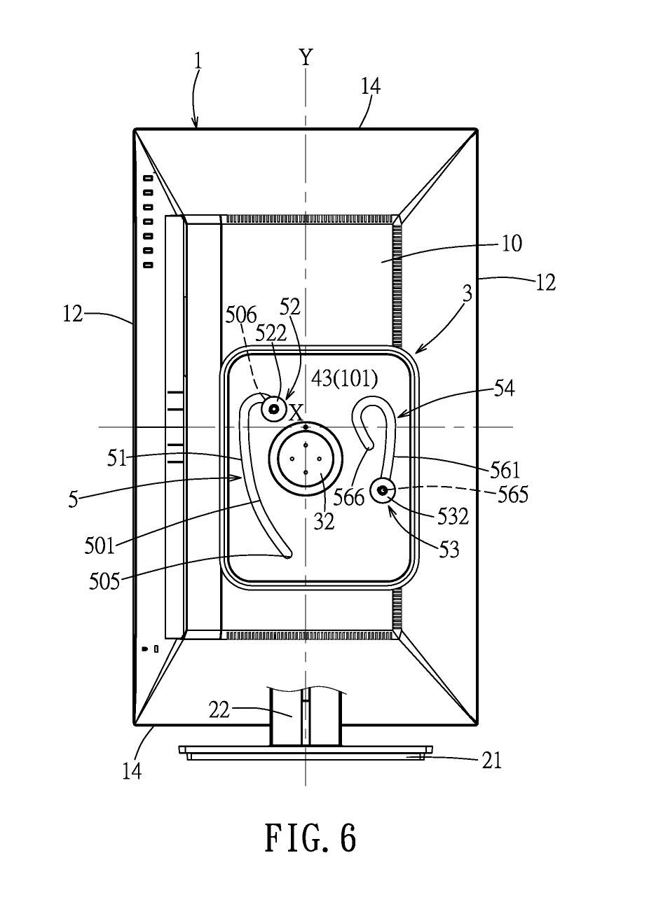

The first curved groove has a lower close end 505, an upper close end 506, and a hook-shaped upper section 507 that extends between the lower and upper close ends 505, 506, that is terminated at the upper close end 506 and that has an uphill sub-section which extends curvedly and upwardly, and a downhill sub-section which extends curvedly and downwardly from the uphill subsection to the upper close end 506. The second curved groove has a lower close end 565, an upper close end 566, and a hook-shaped upper section 567 that extends between the lower and upper close ends 565, 566 of the second curved groove, that is terminated at the upper close end 566 of the second curved groove, and that has an uphill sub-section which extends curvedly and upwardly, and a downhill sub-section which extends curvedly and downwardly from the uphill subsection to the upper closed end 566 of the second curved groove . The electronic device 1 is turnable relative to the bracket plate 3 between horizontal and vertical positions (see FIGS. 4 and 6, respectively). The shaft portion 521 of the first connector 52 is disposed at the lower closed end 505 of the first curved groove and the shaft portion 531 of the second connector 53 is disposed at the upper closed end 566 of the second curved groove when the electronic device 1 is disposed at the horizontal position. The shaft portion 521 of the first connector 52 is disposed at the upper closed end 506 of the first curved groove and the shaft portion 531 of the second connector 53 is disposed at the lower closed end 565 of the second curved groove when the electronic device 1 is disposed at the vertical position. The horizontal axis (X) intersects the vertical axis (Y) at a first intersecting point 42 (which overlaps the geometric center 101 of the back surface 10 along the horizontal axis (X)) when the electronic device 1 is disposed at the horizontal position, and at a second intersecting point 43 (which overlaps the geometric center 101 of the back surface 10 along the horizontal axis (X)) when the electronic device 1 is disposed at the vertical position. The second intersecting point 43 has a height relative to the base 21 greater than that of the first intersecting point 42. The horizontal axis (x) does not intersect the vertical axis (Y) when the electronic device 1 is disposed at a position off from the horizontal and vertical positions (see FIG. 5).

The second curved groove extends along a second curved and non-circumferential line (s2) (see FIG. 5) that has a shape and a curvature different from those of the first curved and non-circumferential line (s1). In this embodiment, the first and second curved and non-circumferential lines (s1, s2) extend in a manner similar to a spiral path that progressively extends farther away from a spiral center as it revolves around the spiral center.

A fastening plate 25 interconnects securely the top end of the upright post 22 and a central portion 32 of the bracket plate 3 through fasteners (not shown). The first and second curved grooves are disposed at two opposite sides of the fastening plate 25, respectively.

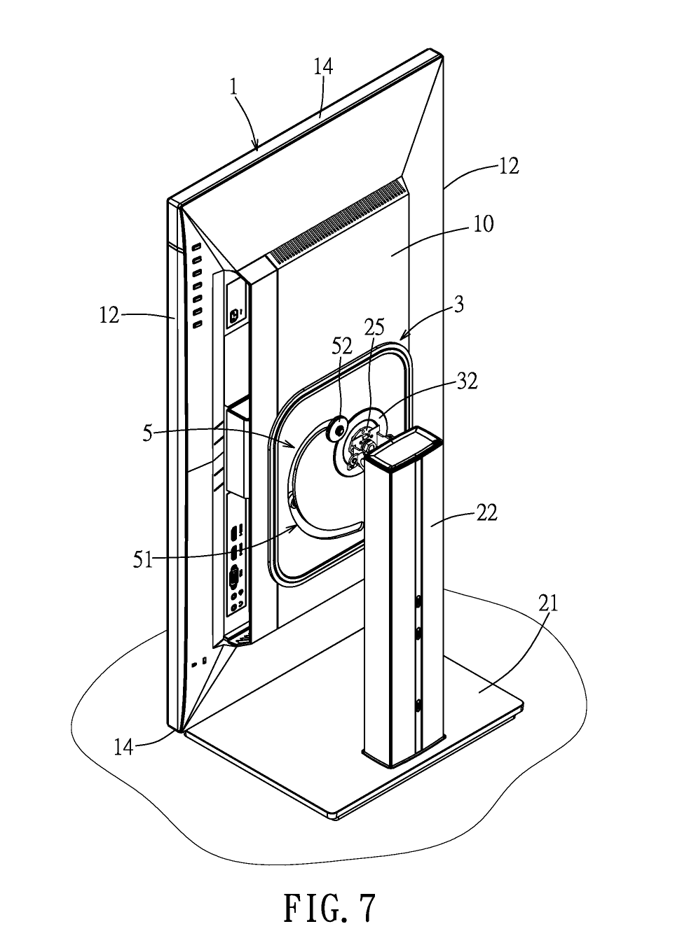

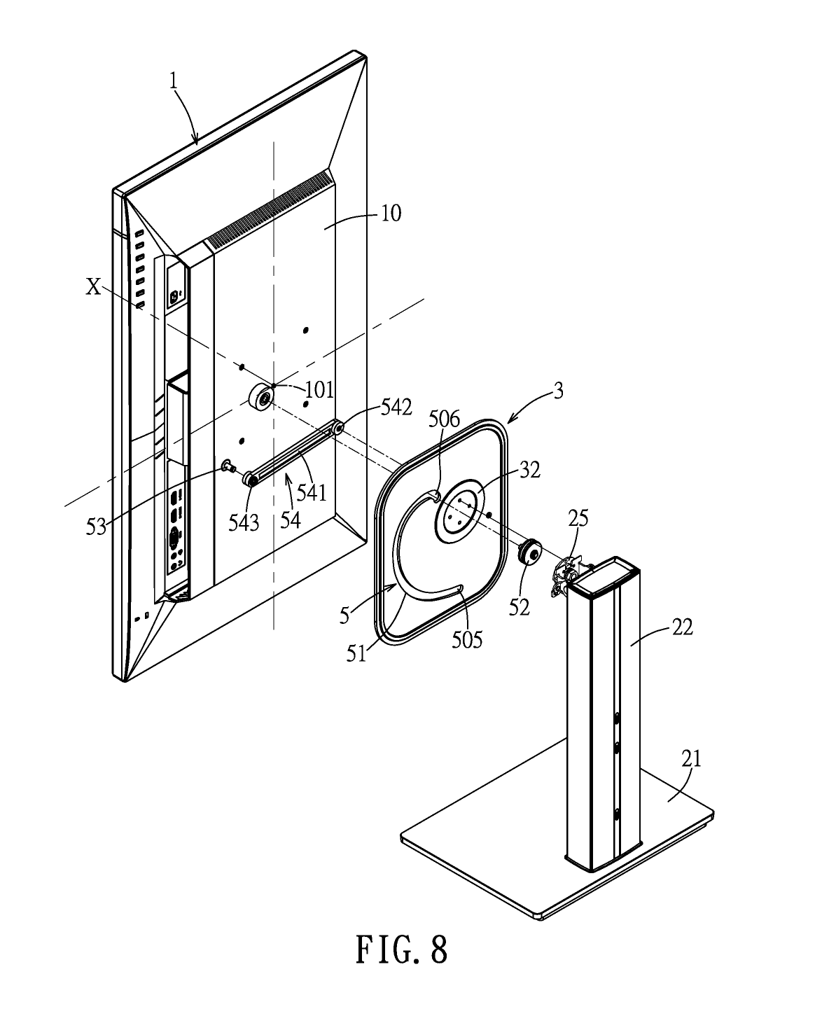

FIGS. 7 to 12 illustrate the second preferred embodiment of the device adjustable support according to the present invention. The second preferred embodiment differs from the previous embodiment in that the second connector 53 is in the form of a pivot shaft which is secured to and protrudes outwardly from the back surface 10 of the electronic device 1, and that the course-keeping member 54 has a linking rod 541 and a pivot pin 545 which is secured to and protrudes outwardly from the bracket plate 3. The linking rod 541 has two opposite ends 542, 543 that are pivoted to the pivot pin 545 and the pivot shaft (i.e., the second connector 53), respectively.

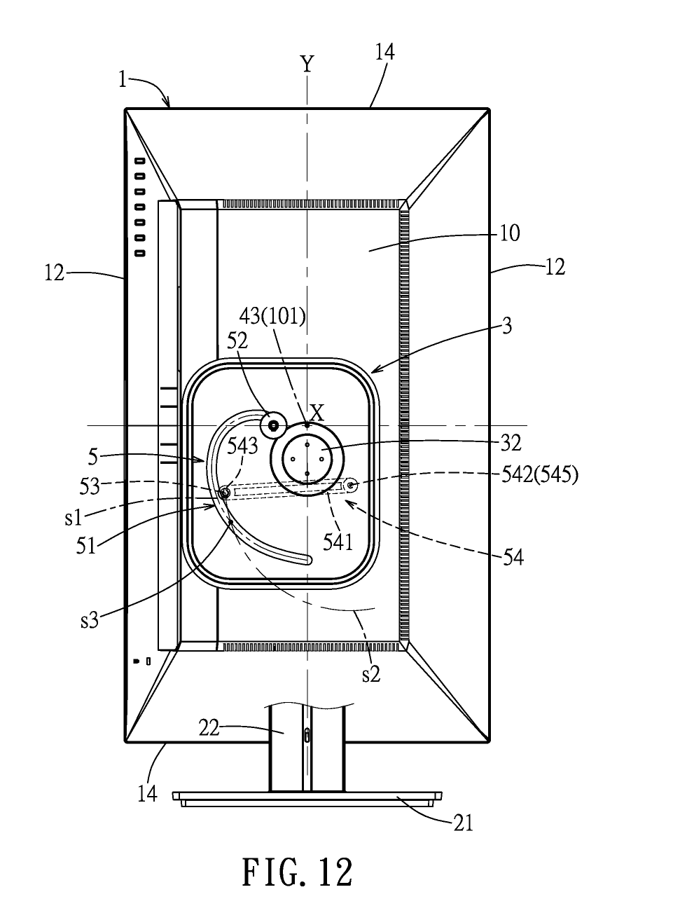

In this embodiment, the second connector 53 rotates along a circumferentially-extending line (s2) about the pivot pin 545 when the first connector 52 is moved along the first curved and non-circumferential line (s1). The circumferentially-extending line (s2) intersects the first curved and non-circumferential line (s1) at an intersecting point (s3) (see FIG. 12).

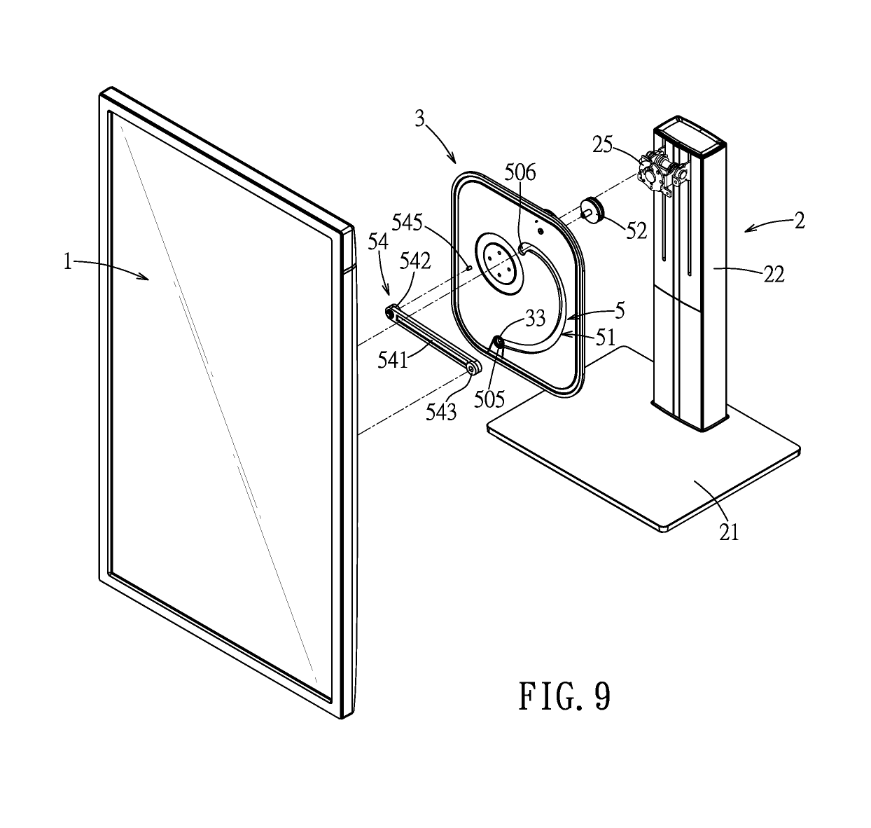

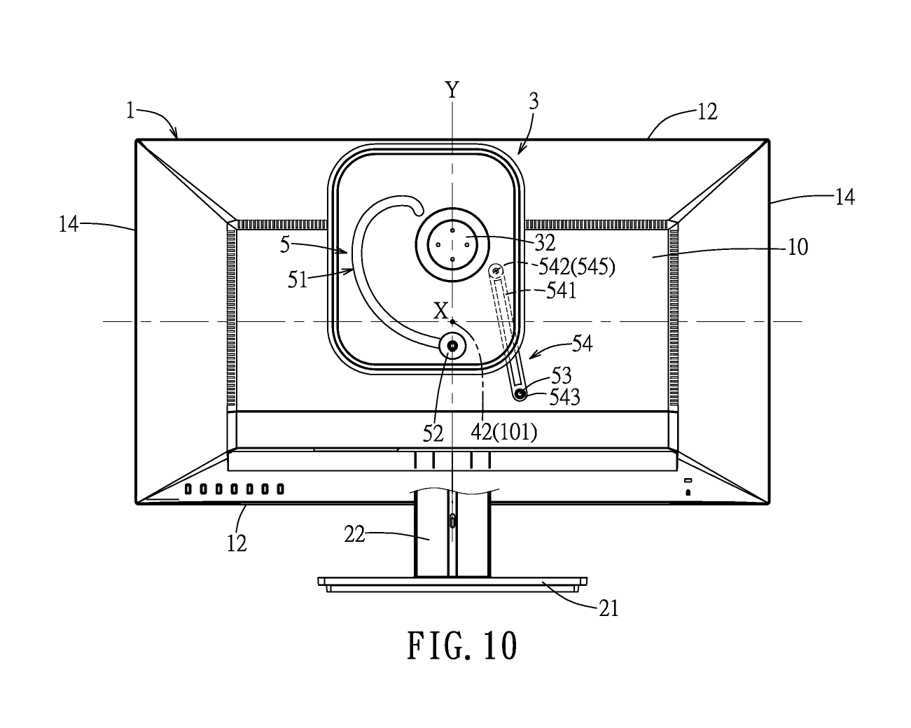

A torsion spring 33 is secured to the bracket plate 3 (see FIG. 9) , and is disposed adjacent to the lower close end 505 of the first curved groove (i.e., the guide track 51) for urging the first connector 52 to serve as a cushion for the electronic device 1 when the first connector 52 is turned from the vertical position (see FIG. 12) to the horizontal position (see FIG. 10).

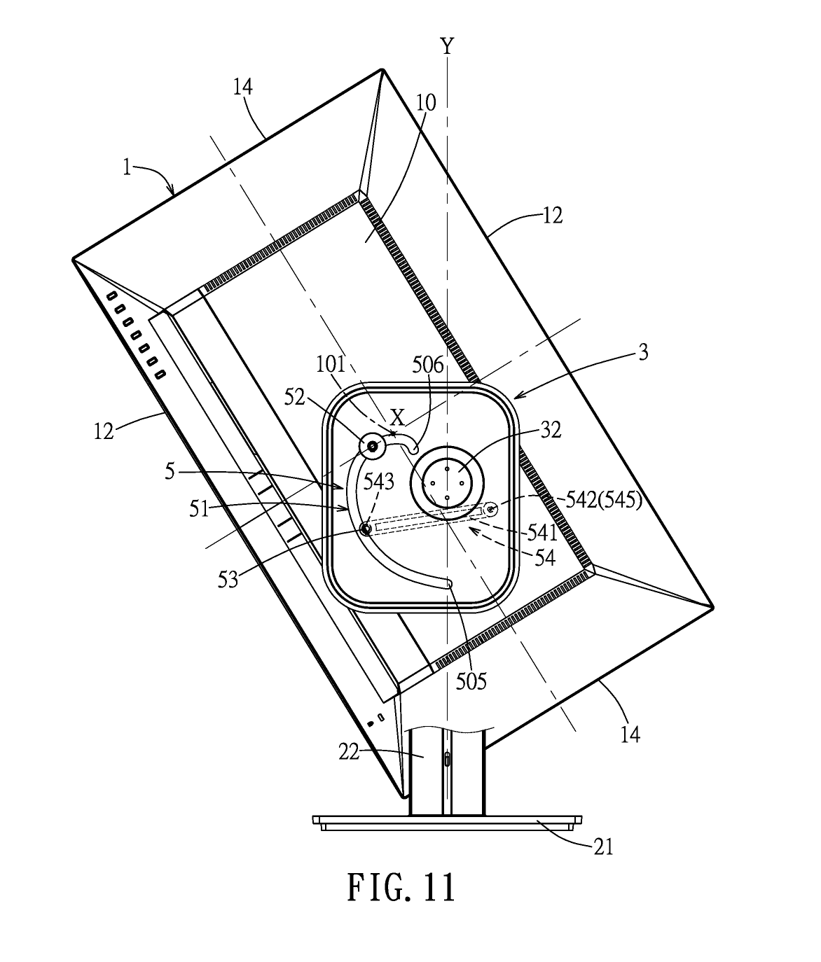

Similar to the previous embodiment, the horizontal axis (X) intersects the vertical axis (Y) at a first intersecting point 42 when the electronic device 1 is disposed at the horizontal position, and at a second intersecting point 43 when the electronic device 1 is disposed at the vertical position. The second intersecting point 43 has a height relative to the base 21 greater than that of the first intersecting point 42. The horizontal axis (x) does not intersect the vertical axis (Y) when the electronic device 1 is disposed at a position off from the horizontal and vertical positions (see FIG. 11).

With the inclusion of the guiding track 51 and the course-keeping member 54 of the coupling mechanism 5 of the device adjustable support of this invention, the aforesaid drawback associated with the prior art can be alleviated.

While the present invention has been described in connection with what are considered the most practical and preferred embodiments, it is understood that this invention is not limited to the disclosed embodiments but is intended to cover various arrangements included within the spirit and scope of the broadest interpretation and equivalent arrangements.

What is claimed is:

1. A device adjustable support for adjustably supporting an electronic device, said device adjustable support comprising:
a bracket plate; and
a coupling mechanism that is adapted to couple the electronic device to said bracket plate;
wherein said coupling mechanism includes:
a guiding track that is securely integrated with said bracket plate and that extends along a first curved and non-circumferential line,
a course-keeping member that is integrated with said bracket plate,
a first connector that is adapted to be secured to a surface of the electronic device and that is connected slidably to said guiding track so as to be slidable on said bracket plate along said first curved and non-circumferential line, and
a second connector that is adapted to be secured to the surface of the electronic device, that is spaced apart from said first connector, and that is connected movably to said course-keeping member so as to keep sliding movement of said first connector along said guiding track when the electronic device is simultaneously turned and changed in height relative to said bracket plate.

2. The device adjustable support of claim 1, wherein said bracket plate is formed with a first curved groove that is defined by a first groove-defining wall and that serves as said guiding track, said first connector having a shaft portion and a head portion, said shaft portion being adapted to be connected to and extend from the electronic device through the first curved groove so as to be slidable on said first groove-defining wall, said head portion being anchored at one side of said bracket plate opposite to the electronic device.

3. The device adjustable support of claim 2, wherein said bracket plate is further formed with a second curved groove that is defined by a second groove-defining wall and that serves as said course-keeping member, said second connector having a shaft portion and a head portion, said shaft portion of said second connector being adapted to be connected to and extend from the electronic device through the second curved groove so as to be slidable on said second groove-defining wall, said head portion of said second connector being anchored at one side of said bracket plate opposite to the electronic device.

4. The device adjustable support of claim 3, wherein said first curved groove has a lower close end, an upper close end, and a hook-shaped upper section that extends between said upper and lower close ends of said first curved groove and that is terminated at said upper close end, said second curved groove having a lower close end, an upper close end, and a hook-shaped upper section that extends between said upper and lower close ends of said second curved groove and that is terminated at said upper close end of said second curved groove, the electronic device being turnable relative to said bracket plate between horizontal and vertical positions, said shaft portion of said first connector being disposed at said lower closed end of said first curved groove and said shaft portion of said second connector being disposed at said upper closed end of said second curved groove when the electronic device is disposed at the horizontal position, said shaft portion of said first connector being disposed at said upper closed end of said first curved groove and said shaft portion of said second connector being disposed at said lower closed end of said second curved groove when the electronic device is disposed at the vertical position.

5. The device adjustable support of claim 4, wherein said second curved groove extends along a second curved and non-circumferential line that has a shape different from that of said first curved and non-circumferential line.

6. The device adjustable support of claim 4, further comprising an upright post and a fastening plate that interconnects securely said upright post and said bracket plate, said first and second curved grooves being disposed at two opposite sides of said fastening plate, respectively.

7. The device adjustable support of claim 2, wherein said second connector is in the form of a pivot shaft that is adapted to be secured to and protrude outwardly from the electronic device, said course-keeping member having a linking rod and a pivot pin that is secured to said bracket plate, said linking rod having two opposite ends that are pivoted to said pivot shaft and said pivot pin, respectively.

8. The device adjustable support of claim 7, wherein said first curved groove has a lower close end, an upper close end, and a hook-shaped upper section that extends between said upper and lower close ends and that is terminated at said upper close end.

9. The device adjustable support of claim 8, wherein said pivot shaft rotates along a circumferentially-extending line about said pivot pin when said first connector is moved along said first curved and non-circumferential line, said circumferentially-extending line intersecting said first curved and non-circumferential line.
